(19) United States
(12) Patent Application Publication
(10) Pub. No.: US 2008/0194091 A1
(43) Pub. Date: Aug. 14, 2008

(54) Method for fabricating nitrided oxide layer

(75) Inventors: Su-Horng Lin, Hsinchu (TW); Hsuan-Yih Chu, Taipei (TW); Chi-Ming Yang, Hsinchu (TW)

Correspondence Address: BIRCH, STEWART, KOLASCH & BIRCH, LLP, P.O. BOX 747, FALLS CHURCH, VA, 22040-0747, US

(73) Assignee: TAIWAN SEMICONDUCTOR MANUFACTURING CO., LTD.

(21) Appl. No.: 11/705,435

(22) Filed: Feb. 13, 2007

(51) Int. Cl. H01L 21/31; H01L 21/3205

(52) U.S. Cl. 438/591; 438/775; 257/E21.24; 257/E21.294

(57) ABSTRACT

A method for fabricating a nitrided oxide layer. A plasma reactor including a pedestal for supporting a substrate is provided. A substrate having an oxide layer thereon is placed on the pedestal. Nitridation of the oxide layer is performed by exposing the substrate to decoupled nitrogen plasma, wherein a positive bias is applied to the pedestal during the nitridation to reduce a potential drop between the plasma and the substrate surface.

### BACKGROUND OF THE INVENTION

1. Field of the Invention

The invention relates to semiconductor manufacturing, and in particular to a method for fabricating a nitrided oxide layer.

2. Description of the Related Art

With trends in integrated circuits toward higher performance, higher speed and lower cost, device dimensions and element sizes are being reduced and gate dielectrics must scale accordingly. As physical gate dielectric thickness decreases, the need for a higher dielectric constant and less leaky gate dielectric has arisen.

Heavily nitrided gate oxide has been employed in advanced integrated circuit technology for reducing oxide leakage current and suppressing boron penetration in p-channel metal-oxide-semiconductor field-effect transistors (MOSFETs). Nitrogen is believed to block boron penetration by forming B—N complexes. The amount of nitrogen incorporated into the gate oxide generally determines the effectiveness of the oxide layer in blocking boron diffusion. Traditional nitrided oxide films prepared using NO or N₂O thermal nitridation, however, cannot achieve a high level of incorporation of nitrogen into the oxide film. Decoupled plasma nitridation (DPN) is a new technology using inductive coupling to generate nitrogen plasma and incorporate a high level of nitrogen uniformly onto the top surface of an ultra-thin gate oxide, increasing the dielectric constant of the gate dielectric, thus reducing equivalent oxide thickness (EOT) and improving the boron penetration problem in p-channel MOSFETs. Traditional nitrided oxide prepared using NO or N₂O thermal nitridation, however, piles up nitrogen at the oxide/substrate interface, which results in boron pile-up within the oxide, causing an increase in electron trapping and degradation of oxide reliability. DPN of the gate oxide results in less nitrogen at the oxide/substrate interface and higher nitrogen concentration at the oxide/polysilicon gate interface. This results in less boron pile-up within the oxide and improves boron penetration problems.

Although DPN can achieve high nitrogen incorporation, nitrogen ion bombardment causes damage to the oxide/substrate interface, leading to deterioration of gate oxide integrity. This issue becomes increasingly important as physical gate oxide thickness continues to decrease, because a higher nitrogen dosage is required to suppress boron penetration. Remote plasma nitridation (RPN), which involves generating nitrogen plasma outside of the process chamber, can effectively avoid ion bombardment to gate oxide. Unfortunately, RPN cannot provide high nitrogen incorporation.

Therefore, there exists a need for a method for fabricating a nitrided gate oxide with high nitrogen dosage while ensuring minimal impact on gate oxide integrity.

### BRIEF SUMMARY OF THE INVENTION

A general object of the invention is to reduce wafer damage caused by ion bombardment during a decoupled plasma nitridation (DPN) process.

According to one aspect of the invention, there is provided a method for fabricating a nitrided oxide layer, comprising providing a plasma reactor including a pedestal for supporting a substrate, placing a substrate on the pedestal, the substrate having an oxide layer thereon, and performing nitridation of the oxide layer by exposing the substrate to a decoupled nitrogen plasma, wherein a positive bias is applied to the pedestal during the nitridation.

According to another aspect of the invention, there is provided a method for fabricating a gate stack, comprising forming a silicon oxide layer on a substrate, providing a plasma reactor including a pedestal for supporting a substrate, placing the substrate on the pedestal, and performing nitridation of the silicon oxide layer to form a silicon oxynitride layer by exposing the substrate to a decoupled nitrogen plasma, wherein a positive bias is applied to the pedestal during the nitridation, annealing the silicon oxynitride layer, and forming a polysilicon layer on the silicon oxynitride layer, thus forming the gate stack.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is an idealized graph of an oscillating voltage profile of a conventional decoupled plasma reactor pedestal;

FIG. 2 is a schematic view of a decoupled plasma reactor providing nitridation of the invention; and

FIG. 3 is an idealized graph of an oscillating voltage profile of a decoupled plasma reactor pedestal according to the invention;

FIGS. 4-6 are cross sections illustrating fabrication of a gate stack according to an embodiment of the invention; and

FIG. 7 is a cross section illustrating the fabrication of a MOSFET following the formation of the gate stack according to the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The terms nitrided silicon oxide and silicon oxynitride (SiOxNy) are equivalent terms for the purposes of the invention. The scope of SiOxNy includes all combinations of integers x and y (or fractions thereof) at which SiOxNy is stable. The term nitrided oxide is meant to include nitrided silicon oxide, nitrided gate oxide and nitrided gate dielectrics.

A plasma consists of electrons, ions, radicals and stable neutral particles. In a plasma reactor, because the electrons are much more mobile than the ions, they initially strike the walls of the reactor chamber at a greater rate than do the ions. The effect of this is that the plasma body becomes slightly electron-deficient while the boundary layer sheath becomes substantially electron-deficient. Accordingly, plasma consists of substantially neutral, conductive plasma body and an electron-deficient boundary layer called the plasma sheath. The plasma sheath forms between the plasma body and any interface such as the walls and electrodes of the plasma reactor chamber and the RF electrodes.

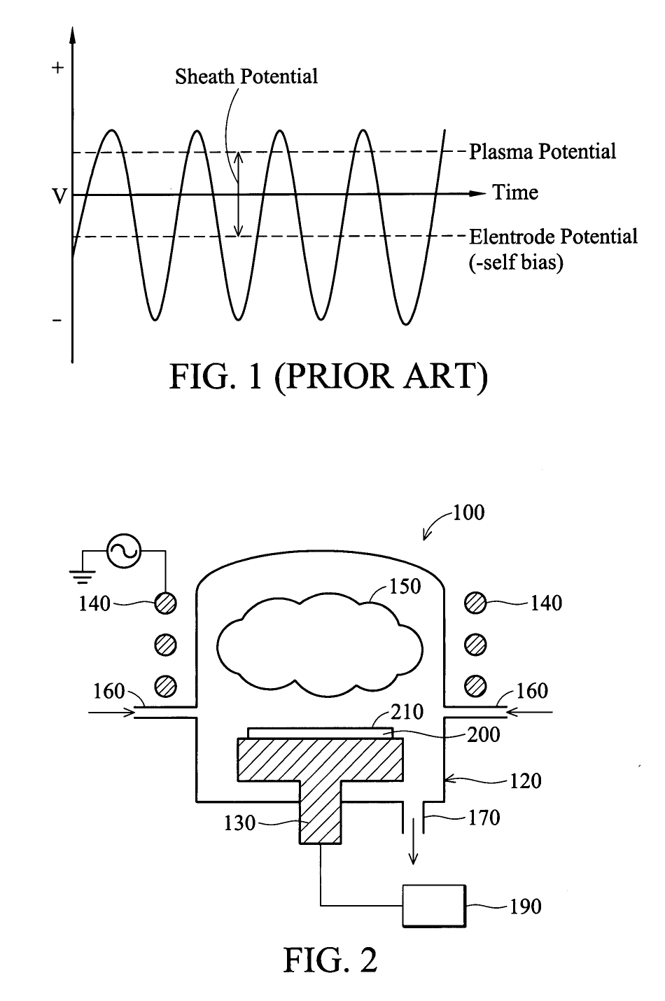

FIG. 1 is an idealized graph of an oscillating voltage profile of a conventional decoupled plasma reactor pedestal. A semiconductor wafer is held against a grounded pedestal. In operation, the RF power discharge generates plasma and a negative self-bias between the driven electrode and the wafer on the grounded pedestal. As shown in FIG. 1, the sheath potential is defined as the difference between the plasma potential and electrode (wafer) potential. The sheath potential determines the maximum energy of the ions bombarding the wafer surface.

The invention predominantly confines nitrogen ion bombardment to the top interface of an oxide layer. To this end, the ion bombarding energy is reduced by adjusting the self-bias voltage to reduce sheath potential. A positive bias applied to the pedestal during the DPN process reduces ion bombardment energy and leads to radical nitridation as a result of charge repulsion.

FIG. 2 is a schematic view of a decoupled plasma reactor for performing nitridation of the invention. It should be noted that apparatus other than that shown in FIG. 2 can be used to practice the invention. In FIG. 2, the decoupled plasma reactor 100 includes a chamber 120 and a wafer pedestal 130 (for holding a wafer 200) within the chamber. The wafer pedestal 130 is connected to a suitable power source 190 such as AC power source. Radio frequency (RF) coils 140 generata plasma 150 above wafer 200. Gases for plasma 150 are supplied by inlets 160 in sidewalls of chamber 185. Chamber 120 also includes a vacuum port 170 in a surface of the chamber.

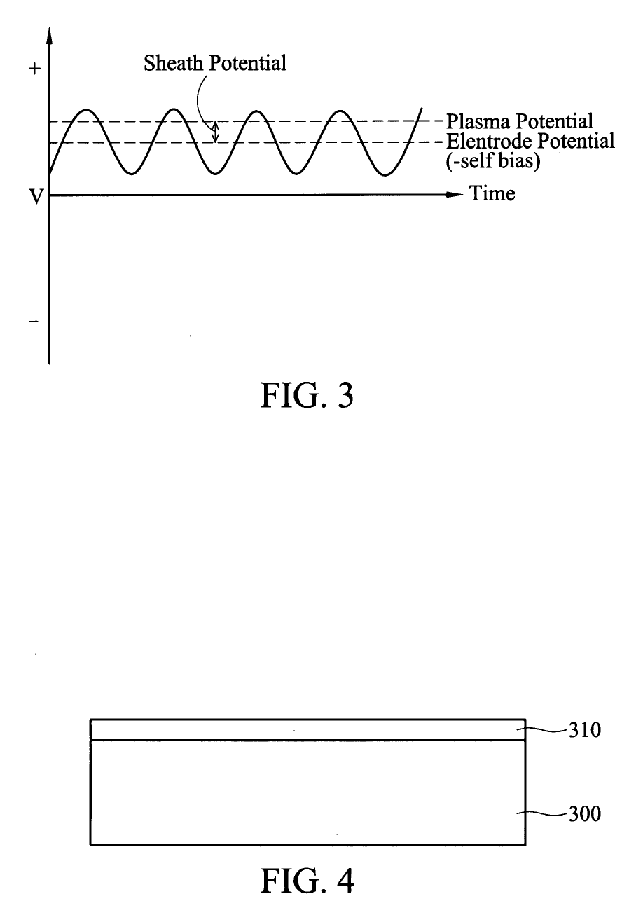

In operation, a wafer 200 having an oxide layer such as nitrided silicon oxide, nitrided gate oxide and nitrided gate dielectrics on a top surface 210 thereof is placed into the chamber 120 from a transfer chamber (not shown), a gas mixture of nitrogen and inert gas (He, for example) is introduced into the chamber via inlets 160 and the chamber is maintained at a pre-selected pressure via a pump attached to vacuum port 170. RF power is impressed on RF coils 140 to energize and maintain plasma 150. A positive RF bias from the pedestal power source 190 is applied to reduce the potential difference between the plasma 150 and the wafer 200. FIG. 3 shows an idealized graph of an oscillating voltage profile of the decoupled plasma reactor pedestal according to the invention. As shown in FIG. 3, since the electrode (wafer) potential is elevated by positive RF bias, the sheath potential drop is reduced and the ion bombardment energy limited to a low level. In preferred embodiments, the sheath potential drop is controlled between 0 and 100V, more preferably between 0 and 50V. In addition, as the positive polarity of the wafer is repulsive to positive nitrogen ions, nitrogen radicals become primary agents responsible for the nitridation, while nitrogen ions are secondary agents responsible for the nitridation. Accordingly, the nitrogen profile can be confined and preferably forms a nitrogen concentration peak at the top surface of the oxide layer. After a pre-selected time, the RF power is turned off to extinguish plasma 150, the gas flow is turned off and chamber 120 is brought up to transfer chamber pressure. One example of decoupled plasma system is a Centura 5200 system manufactured by Applied Materials Corp, Santa Clara, Calif.

FIGS. 4-6 are cross sections illustrating fabrication of a gate stack according to an embodiment of the invention. In FIG. 4, a substrate 300 is provided. The substrate 100 may be an intrinsic, N-type or P-type bulk silicon substrate, an undoped or intrinsic, N-type or P-type silicon on insulator (SOI) substrate, a sapphire substrate, or a ruby substrate. An oxide layer, preferably a silicon oxide layer 310 is formed on the top surface of substrate 300. Prior to formation of the silicon oxide layer 310, the substrate surface is cleaned by any one of a number of cleaning processes well known in the art. For example, substrate 300 may be cleaned using a buffered hydrofluoric acid (BHF) clean followed by an NH₄OH clean followed by an HCl clean. If the substrate 300 is a bulk silicon substrate or an SOI substrate, the silicon oxide layer 310 may be formed, in a first example, by a thermal oxidation in a furnace in an oxygen-containing atmosphere at about 600 to 800° C. for about 0.5 to 30 minutes. In a second example, the silicon oxide layer 310 may be formed by a rapid thermal oxidation (RTO) in an oxygen-containing atmosphere at about 800 to 1000° C. for about 5 to 60 seconds. In a third example, the silicon oxide layer 310 may be formed by thermal oxidation in a gaseous environment containing oxygen and either nitric oxide (NO) or nitrous oxide (N₂O) such that silicon oxide layer 310 contains from 0 to 5% atomic percent nitrogen. If the substrate 300 is a ruby or sapphire substrate, the silicon oxide layer 310 may be formed by deposition in a chemical vapor deposition (CVD) tool and the oxide layer may be a tetraethoxysilane (TEOS) oxide. TEOS may also be used for a bulk silicon or SOI substrate. Preferably, the oxide layer has a thickness not exceeding 20 Å, for example, between 10 Å and 20 Å.

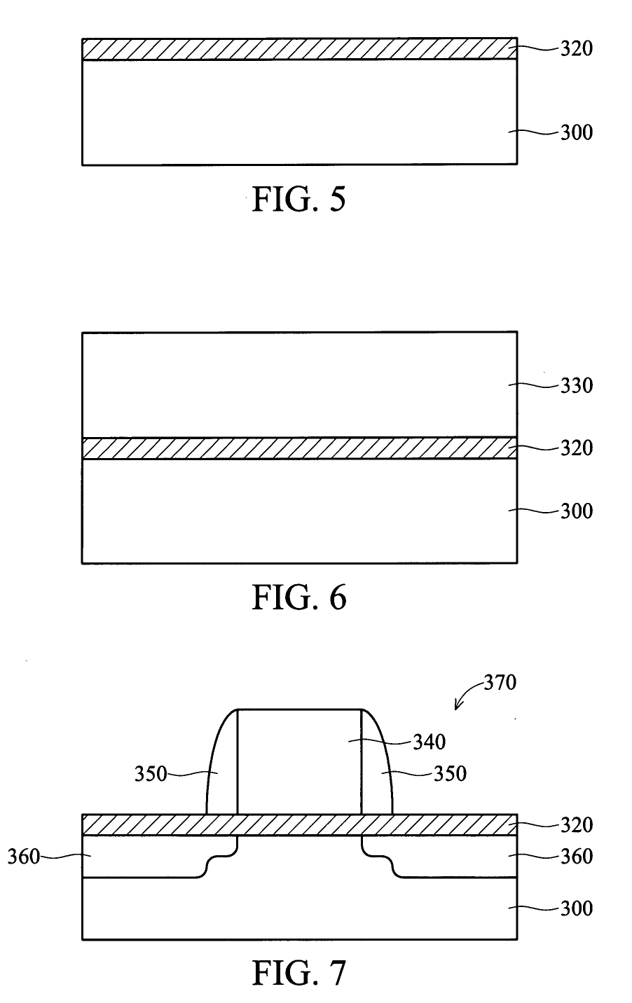

In FIG. 5, a decoupled plasma nitridation (DPN) process is performed to convert the silicon oxide layer 310 to a nitrided oxide (SiOxNy) layer 320. The nitridation process can be performed in a reactor as depicted in FIG. 2 or any other suitable DPN reactor where the wafer pedestal is positively biased. In one embodiment, the DPN is performed in a chamber with pressure ranging from about 5-20 mTorr or 10-20 mTorr, with a plasma power of about 200-1500 W. 0 to 100V, preferably 0 to 50V of AC bias is applied to the supporting pedestal. The nitrogen gas may enter the chamber at a flow rate ranging from about 100-200 sccm. In one embodiment, the DPN uses a pulse radio frequency plasma process at about 10-20 mHz and pulse at about 5-15 kHz. The DPN process parameters can be modified depending on the chamber size and volume and the thickness of the dielectric film. The nitrided oxide (SiOxNy) layer 320 may be a few A thicker than the silicon oxide layer 310 and preferably contains 5% nitrogen atoms or more. Afterwards, the substrate 300 can be transferred to a rapid thermal processing chamber for an optional post nitridation annealing. The post nitridation anneal can take place at about 700-1100° C. in either inert or oxidizing ambient.

In FIG. 6, a gate electrode layer such as a polysilicon layer 330 is formed on a top surface of the nitrided oxide layer 320, thus completing a gate stack. The polysilicon layer 330 may be formed using one of a number of deposition processes well known in the art, such as low-pressure chemical vapor deposition (LPCVD) or rapid thermal chemical vapor deposition (RTCVD). The polysilicon layer 330 may be undoped or doped N-type or P-type. In one example, polysilicon layer 330 is 1000 to 2000 Å thick. The fabrication of the gate stack including the nitrided oxide layer 320 and polysilicon layer 330 can be accomplished in a cluster tool. That is, the formation of the silicon oxide layer 310, the plasma nitridation, the post nitridation anneal, and the formation of the polysilicon layer 330 are performed in four different chambers of a cluster tool without breaking vacuum.

FIG. 7 illustrates the fabrication of a MOSFET following the formation of the gate stack. In FIG. 7, a polysilicon layer 330 is etched, for example, by reactive ion etching (RIE) to form a gate electrode 340. Spacers 350 are formed on sidewalls of gate electrode 340. Formation of source/drains 360 (typically by one or more ion-implantation processes) essentially completes fabrication of a MOSFET 370, with the nitrided oxide layer 320 being the gate dielectric of the MOSFET. If polysilicon layer 330 (see FIG. 6) was not doped during deposition, the gate electrode 340 may be doped N-type or P-type after spacer formation by ion implantation in conjunction with the formation of the source/drains 360 or as a separate step. As the nitrided oxide layer 320 is formed with lower ion bombardment energy and predominately by radical reaction, the detrimental effects of the DPN process on gate oxide integrity decreased, and the reliability of the MOSFET 370 thus improved.

It should be noted that, although the embodiments concern nitridation of a silicon oxide film, the method of the invention is not limited thereto and may be used in nitridation of other oxide films. Furthermore, although the disclosure is made with reference to the fabrication of a MOSFET, the invention is not limited thereto and it is applicable to other semiconductor devices that require a nitrided oxide layer.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for fabricating a nitrided oxide layer, comprising:
providing a plasma reactor including a pedestal for supporting a substrate;
placing a substrate on the pedestal, the substrate having an oxide layer thereon; and
performing nitridation of the oxide layer by exposing the substrate to a decoupled nitrogen plasma,
wherein a positive bias is applied to the pedestal during the nitridation.

2. The method as claimed in claim 1, wherein the nitridation forms a nitrogen concentration peak at the top surface of the oxide layer.

3. The method as claimed in claim 1, wherein nitrogen radicals are primary agents responsible for the nitridation.

4. The method as claimed in claim 3, wherein nitrogen ions are secondary agents responsible for the nitridation.

5. The method as claimed in claim 1, wherein the positive bias is a positive RF bias.

6. The method as claimed in claim 1, wherein the positive bias is about 0 to 100V.

7. The method as claimed in claim 1, wherein a potential drop between the decoupled nitrogen plasma and the substrate is less than about 100V.

8. The method as claimed in claim 1, wherein the oxide layer comprises a silicon oxide layer.

9. The method as claimed in claim 1, wherein the nitrided oxide layer has a nitrogen concentration equal to or greater than 5%.

10. The method as claimed in claim 1, further comprising performing a post nitridation anneal on the substrate.

11. A method for fabricating a gate stack, comprising:
forming a silicon oxide layer on a substrate;
providing a plasma reactor including a pedestal for supporting a substrate;
placing the substrate on the pedestal; and
performing nitridation of the silicon oxide layer to form a silicon oxynitride layer by exposing the substrate to a decoupled nitrogen plasma, wherein a positive bias is applied to the pedestal during the nitridation;
annealing the silicon oxynitride layer; and
forming a gate electrode layer on the silicon oxynitride layer, thus forming the gate stack.

12. The method as claimed in claim 11, wherein the silicon oxide layer is formed by thermal oxidation, rapid thermal oxidation, or chemical vapor deposition.

13. The method as claimed in claim 11, wherein the nitridation forms a nitrogen concentration peak at the top surface of the silicon oxide layer.

14. The method as claimed in claim 11, wherein nitrogen radicals are primary agents responsible for the nitridation.

15. The method as claimed in claim 11, wherein the positive bias is a positive RF bias.

16. The method as claimed in claim 11, wherein the positive bias is about 0 to 100V.

17. The method as claimed in claim 11, wherein a potential drop between the decoupled nitrogen plasma and the substrate is less than about 100V.

18. The method as claimed in claim 11, wherein the silicon oxide layer has a thickness not exceeding 20 Å.

19. The method as claimed in claim 11, wherein the silicon oxynitride layer has a nitrogen concentration equal to or greater than 5%.

20. The method as claimed in claim 11, wherein the formation of the silicon oxide, the nitridation, the annealing, and the formation of the gate electrode layer are performed in different chambers of a cluster tool without breaking vacuum.
